(19) United States
(12) Patent Application Publication
(10) Pub. No.: US 2006/0108672 A1
(43) Pub. Date: May 25, 2006

(54) Die bonded device and method for transistor packages

(76) Inventors: John M. Brennan, Wyomissing, PA (US); Joseph Michael Freund, Fogelsville, PA (US); John W. Osenbach, Kutztown, PA (US); Hugo F. Safar, Westfield, NJ (US); Richard Shanaman III, Richland, PA (US)

Correspondence Address: Law Firm of Peter V.D. Wilde, 301 East Landing, Williamsburg, VA, 23185, US

(21) Appl. No.: 10/996,677

(22) Filed: Nov. 24, 2004

(51) Int. Cl. H01L 23/495; H01L 23/24; H01L 23/02

(52) U.S. Cl. 257/676; 257/687; 257/678

(57) ABSTRACT

The specification describes a technique for die bonding that is tailored to air cavity plastic packages for high power devices. The die bonding method is simple and effective, and eliminates the step of placement of solder preforms in the die bonding operation. According to the invention the die that are to be attached are pre-coated with AuSn solder. A multifunctional bonding layer is applied between the silicon die and the AuSn bonding layer. The multifunctional bonding layer comprises a multi-layer structure including Ti/Pt/Au. The chip support member comprises copper or a copper alloy. The chip support member may also be pre-coated with a bonding layer. The pre-coated die is soldered to the chip support member.

### FIELD OF THE INVENTION

This invention relates to bonding transistor die to support frames, and more particularly to die bonding procedures used in connection with low cost plastic packaging.

### BACKGROUND OF THE INVENTION

A common form of packaging for electronic devices such as IC devices is a plastic housing. In the most typical IC plastic package, electronic components are assembled on a metal leadframe and a polymer is molded over the assembly to encapsulate the device. The leadframe serves not only to support the electronic components, but has metal tabs that extend from the overmolded plastic and provide a means to electrically connect to the encapsulated electronic components.

Recent modifications of the molded plastic IC package include an air cavity design wherein the housing for the package is plastic but is pre-molded over a lead frame before the IC device is assembled into the package. This design offers the advantage that the IC chip is not exposed to the rigors and heat of the overmolding step used in the plastic encapsulated (overmolded) package. In this design the IC device environment may be an air cavity, or the cavity may be filled after the IC chip is die and wire bonded. The cavity filling may be any polymer, including polymers that cure at low temperatures. The choice of filling material is wider than the choices available in the case of overmolded plastic packages, since the choice is independent of the material used for the pre-molded plastic housing. Thus in a pre-molded plastic cavity package, the IC chip may still be polymer encapsulated, but the heat required for a typical overmolding step may be avoided.

Leadframes of the prior art typically are square or rectangular and have a center paddle to which the semiconductor chip is die bonded. Leadframes are typically stamped from copper or copper alloy sheets. The leads that provide electrical interconnection extend from the sides of the paddle, often along two opposing edges of the leadframe. The number of leads may vary widely. Common RF power devices, for example, RFLDMOS devices, may have only a few leads, one per side for each transistor. A typical RFLDMOS package has from 1-4 transistors.

The conventional method for attaching the IC die to the leadframe employs solder as the bonding medium. The specific bonding operation may take a variety of forms. Solder preforms are commonly used.

Drawbacks to using solder and solder preforms have become evident. When bonding small die, and especially when bonding thin die, the absence of control over the solder reflow creates shorts and other unwanted consequences. A typical LDMOS die may have a thickness as small as 50 microns. In bonding small die, the die is placed on the substrate and the assembly heated. Solder is introduced either as a coating, bump, or ball, on the die or substrate, or both, or as a preform. When heated, the solder reflows to form the bond. The dominant influence in solder reflow is surface tension, a difficult force to control precisely. When the die being attached is thin, the solder may wick up the side of the die sufficiently far to short the leads. If solder preforms are used, the added step of positioning an individual preform at each bond site is added to the process. Moreover, errors in positioning the preforms may occur, resulting in defective bonds.

Recent modifications of the molded plastic IC package include an air cavity design wherein the housing for the package is plastic but is pre-molded over a lead frame before the IC device is assembled into the package. This design offers the advantage that the IC chip is not exposed to the rigors and heat of the overmolding step used in the plastic encapsulated (overmolded) package. In this design the IC device environment may be an air cavity, or the cavity may be filled after the IC chip is die and wire bonded. The cavity filling may be any polymer, including polymers that cure at low temperatures. The choice of filling material is wider than the choices available in the case of overmolded plastic packages, since the choice is independent of the material used for the pre-molded plastic housing. Thus in a pre-molded plastic cavity package, the IC chip may still be polymer encapsulated, but the heat required for a typical overmolding step may be avoided. However, the problems associated with the die-attach method, described above, remain.

### BRIEF STATEMENT OF THE INVENTION

We have devised a method for die bonding that is tailored to air cavity pre-molded plastic packages. The die bonding method is simple and effective, and eliminates the step of placement of solder preforms in the die bonding operation. According to the invention the die that are to be attached are pre-coated with AuSn solder. A multifunctional bonding layer is applied between the silicon die and the AuSn bonding layer. The multifunctional bonding layer comprises a multi-layer structure including Ti/Pt/Au. The chip support member is a simple copper or a copper alloy strip. The chip support member may also be pre-coated with a bonding layer. The pre-coated die is soldered to the chip support member. The invention is aimed at plastic cavity packages but may be used for conventional overmolded plastic packages.

### BRIEF DESCRIPTION OF THE DRAWING

The invention may be better understood when considered in conjunction with the drawing in which:

FIG. 1 is a perspective view of an air cavity plastic package prior to die attachment;

FIG. 2 is a schematic section view through the middle of FIG. 1;

FIG. 3 is a schematic representation of the multifunctional pre-coating for the die, and a pre-coating for the chip support member;

FIG. 4 is a view similar to that of FIG. 3 after die attachment and wire bonding; and

FIG. 5 is a view of the package of FIG. 4 after filling the cavity.

### DETAILED DESCRIPTION OF THE INVENTION

The invention will be described in more detail using as a prototypical package a plastic cavity RFLDMOS power transistor package. The invention was developed around this type of package and it represents a preferred embodiment. However, it should be understood that other kinds of IC devices may be packaged using the approach described.

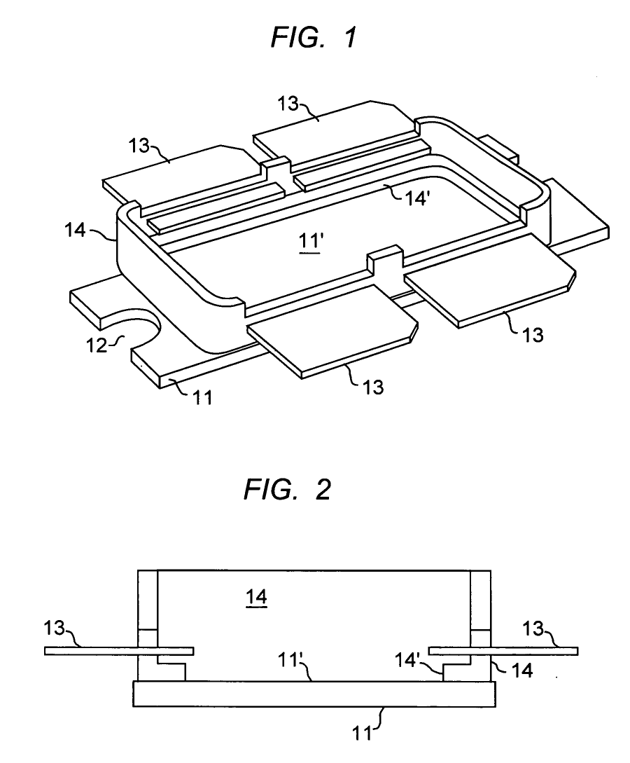

Referring to FIG. 1, a perspective view of a plastic cavity is shown with a metal chip support member 11 comprising at least a portion of what is conventionally considered the lead frame. The metal chip support member 11 is notched at 12 for insertion of a screw or other suitable attachment means to attach the finished IC device to a circuit board or other carrier. This allows the chip support member for the power device to be firmly mounted on the circuit board or on a heat sink, and suitable connectors (not shown) can be attached easily to tab leads 13 on the power device. Molded to the chip support member 11 is a plastic housing 14. The housing comprises four walls and a bottom, preferably all comprising an integral body that encloses a cavity. The center region of the bottom of the plastic housing is open, exposing the portion 11′ of the chip support member inside the cavity. The edge of the opening is seen in FIG. 1 at 14′.

The plastic housing is typically molded to the chip support member by a conventional molding/extrusion process. Anchoring methods may be used to increase the integrity of the attachment. For example, tabs or holes may be formed in the chip support member 11 through which the molded plastic penetrates during molding. These act as anchors after the mold compound cures.

The plastic used for the cavity housing may be selected from a wide variety of polymers. It is particularly desirable to choose a material that will result in a plastic body capable of withstanding the highest temperature possible, so as to facilitate the die attach process.

A main feature of the plastic cavity approach to IC device packaging is that the plastic housing for the package is formed prior to assembling the IC component on the metal support. In the most typical prior art plastic package, the plastic overmolded package, the IC die are attached to a metal lead frame prior to molding the plastic encapsulant around the die and leadframe. This versatile approach has been used to manufacture the vast majority of IC device packages. However, recent trends in IC packaging are toward pre-molded plastic housings, where the plastic housing can be shaped with precision, choice of the material of the plastic housing can be made from a wider selection, the plastic for the housing may be different from the polymer used to encapsulate the IC device, and the IC device is not exposed to the temperatures required for the overmolding process.

A section view of FIG. 1 is shown in FIG. 2. The center portion 11′ of the chip support member 11 is shown clearly. The chip support member is typically copper, or a copper alloy. The chip support member, or optionally just the center region 11′ of the chip support member, may be pre-coated with a solder compatible layer. For example, if the solder to be used is a Au—Sn solder, a barrier layer may be applied to the copper chip support member. The barrier layer may be selected from several choices, for example, Ti, Ni, Ta. The barrier layer may be coated with a strike layer of gold.

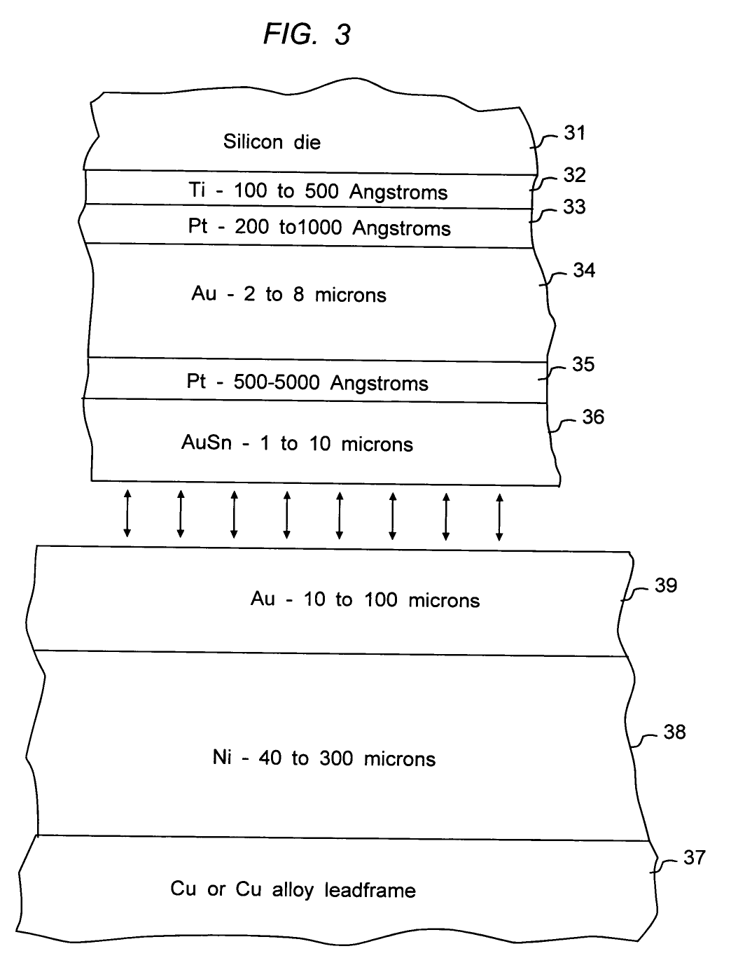

The next operation is to die bond the IC chip to the region 11′ of FIG. 2. As described earlier, prior art die bonding operations typically used conventional solder, usually a lead solder. In accordance with recent environmental engineering requirements, most current die bonding operations use lead-free solder. According to the invention, the RFLDMOS IC chip is pre-coated with a gold solder-compatible die-attach bonding layer. The preferred die-attach bonding layer is the multi-layer structure shown in FIG. 3. FIG. 3 is not to scale.

Referring to FIG. 3, a portion of the RFLDMOS silicon die is shown at 31. It is coated sequentially with:
32. A thin—100 to 500 Angstrom—layer of Ti for increased adhesion of the multifunctional metal layer to the silicon die.
33. A thin—200 tol 000 Angstrom—layer of Pt for providing a barrier between Ti and Au.
34. A relatively thick—2 to 8 micron—layer of Au to mechanically decouple the silicon die and the copper chip support member.
35. A second Pt barrier layer—500 to 5000 Angstroms—providing a barrier to prevent the decoupling Au layer from mixing with the next layer of solder which would both act to change the solder composition and reduce the effectiveness of the decoupling layer.
36. A thick—1 to 10 micron—layer of Au—Sn solder used to form the joint.

The chip support member is shown at 37, and is preferably copper, or a copper alloy. In a preferred example of the invention it is coated sequentially with:
38. 40-300 microns of nickel to provide a barrier layer.
39. 10-100 microns of Au to form a strike layer for the gold-tin solder.

The ranges of layer thickness given above and in FIG. 3 are recommended ranges. Departures from these ranges may be used. The solder material chosen is also given by way of example. However eutectic gold-tin solder, typically 80/20, is desirable for this application from several standpoints. It provides excellent joint strength, and resistance to corrosion. It does not require flux to facilitate joint formation. It has superior thermal conductivity when compared to standard solders. It is especially desirable for power device applications, which often specify a high-melting die-attach solder. With a melting point of 280° C., eutectic AuSn satisfies demanding specifications, which can include device operating at 200 C or higher. However, other solder materials may be substituted. For example, Au—Si, Au—Ge, Au—In and even commonly used Pb-based solder alloys as well as Pb-free solder alloys are suitable gold alloy solder substitutes.

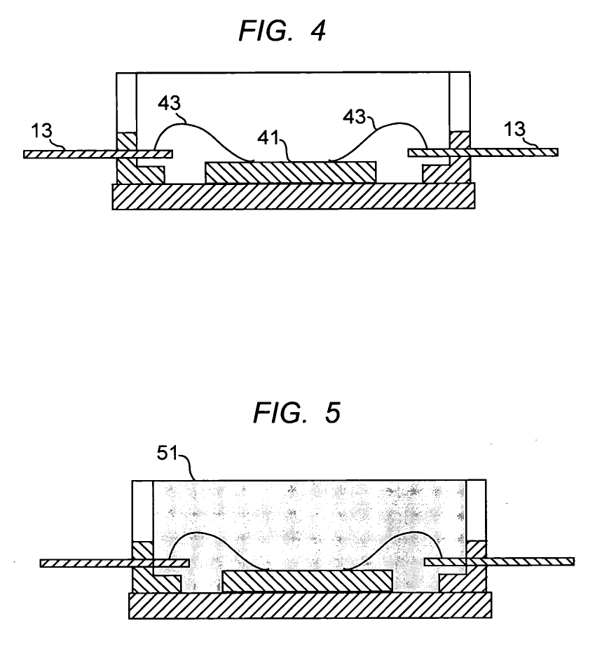

FIG. 4 shows the RFLDMOS silicon die 41, with the pre-coating just described, mounted on region 11′ of the chip support member 11. The region 11′, more typically the entire chip support member 11, is pre-coated as described above. The assembly is then heated to the reflow temperature of the solder to attach the die to the chip support member. The solder reflow temperature for eutectic gold-tin is approximately 280° C.

After die bonding IC chip 41 to the plastic cavity package, the IC chip is connected to leads 13 by wire bonds 43, as shown in FIG. 4.

With assembly of the IC device in the plastic cavity completed, the cavity may be filled with a protective fill 51, as shown in FIG. 5. The pre-molded plastic cavity packaging approach offers the advantage that the plastic housing material and the fill material can be independently chosen. The plastic material for the housing can be chosen for mechanical protection, and is typically a high modulus polymer material. The polymer used as the fill material is typically a material having a low dielectric constant to minimize undesirable parasitic effects on device performance. For example, the plastic cavity housing may be a rigid, thermosetting, polymer, for example a liquid crystal polymer (LCP) such as Ticona Vectra S-135. The fill material may be a thermoplastic polymer, such as Loctite Hysol FP4470.

Various additional modifications of this invention will occur to those skilled in the art. All deviations from the specific teachings of this specification that basically rely on the principles and their equivalents through which the art has been advanced are properly considered within the scope of the invention as described and claimed.

1. A plastic cavity package comprising:
a. a chip support member, the chip support member comprising a metal strip,
b. a plastic housing attached to the chip support member, the plastic housing comprising an integral plastic body with four sides and a bottom, where the bottom has an opening in the center exposing a die-attach portion of the chip support member,
c. a semiconductor die attached to the chip support member,
d. a die-attach layer attaching the semiconductor die to the chip support member, the die-attach layer comprising:
i. a layer of Ti,
ii. a first layer of Pt,
iii. a layer of Au,
iv. a second layer of Pt,
v. a layer of solder.

2. The package of claim 1 wherein the semiconductor die is a silicon chip.

3. The package of claim 2 wherein the chip support member comprises copper or a copper alloy.

4. The package of claim 2 wherein the solder is a gold eutectic compound.

5. The package of claim 4 wherein the chip support member has a coating of a barrier layer.

6. The package of claim 5 wherein the barrier layer comprises a metal selected from the group consisting of Ti and Ni.

7. The package of claim 6 further comprising a gold or gold alloy layer on the barrier layer.

8. The package of claim 4 wherein the layers i.-v. each has a thickness prescribed by:
i. layer of Ti: 100 to 500 Angstroms
ii. first layer of Pt: 200 to 1000 Angstroms
iii. layer of Au: 2 to 8 microns,
iv. second layer of Pt: 500 to 5000 Angstroms,
v. layer of solder: 1 to 10 microns.

9. The package of claim 8 wherein the barrier layer has a thickness in the range 40 to 300 microns.

10. The package of claim 9 wherein the gold or gold alloy layer has a thickness in the range 10 to 100 microns.

11. Method for making a plastic cavity package comprising the step of solder bonding a pre-coated semiconductor die in a plastic cavity package, the plastic cavity package comprising a chip support member and a plastic housing attached to the chip support member, the plastic housing comprising an integral plastic body with four sides and a bottom, where the bottom has an opening in the center exposing a die-attach portion of the chip support member, and the pre-coated semiconductor die having a multi-layer coating comprising:
a. a layer of Ti,
b. a first layer of Pt,
c. a layer of Au,
d. a second layer of Pt,
e. a layer of solder,
the step of solder bonding comprising placing the pre-coated semiconductor die on said die-attach portion of the chip support member, and heating the chip support member to reflow the layer of solder.

12. The method of claim 11 wherein the semiconductor die is a silicon chip.

13. The method of claim 12 wherein the chip support member comprises copper or a copper alloy.

14. The method of claim 13 wherein the solder is a gold eutectic compound.

15. The method of claim 14 wherein the metal chip support member has a coating of a barrier layer.

16. The method of claim 15 wherein the barrier layer comprises a metal selected from the group consisting of Ti and Ni.

17. The method of claim 16 further comprising a gold or gold alloy layer on the barrier layer.

18. The method of claim 17 wherein the layers i.-v. have a thickness in the following ranges:
i. layer of Ti: 100 to 500 Angstroms
ii. first layer of Pt: 200 to 1000 Angstroms
iii. layer of Au: 2 to 8 microns,
iv. second layer of Pt: 500 to 5000 Angstroms,
v. layer of solder: 1 to 10 microns.

19. The method of claim 18 wherein the barrier layer has a thickness in the range 40 to 300 microns.

20. The method of claim 17 wherein the gold or gold alloy layer has a thickness in the range 10 to 100 microns.

21. A plastic package comprising:
a. a chip support member, the chip support member comprising a metal strip,
b. a semiconductor die attached to the chip support member,
c. a die-attach layer attaching the semiconductor die to the chip support member, the die-attach layer comprising:
i. a layer of Ti,
ii. a first layer of Pt,
iii. a layer of Au,
iv. a second layer of Pt,
v. a layer of solder,
d. a plastic body enclosing the chip support member and the semiconductor die.
